(19) United States
(12) Patent Application Publication
(10) Pub. No.: US 2010/0277878 A1
(43) Pub. Date: Nov. 4, 2010

(54) MOUNTING STRUCTURE

(75) Inventor: Takanori SEKIDO, Tokyo (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/840,589

(22) Filed: Jul. 21, 2010

Related U.S. Application Data
(63) Continuation of application No. PCT/JP2009/000090, filed on Jan. 13, 2009.

(30) Foreign Application Priority Data
Jan. 22, 2008 (JP) JP 2008-011492

(51) Int. Cl. H05K 7/00

(52) U.S. Cl. 361/749

(57) ABSTRACT

There is provided a mounting structure in which, it is possible to regulate positions of mounting components, or in other words, an angle of bending of the circuit board, without using any jigs etc., and it is possible to dispose mounting components at arbitrary positions without inhibiting small-sizing of the mounting structure and of a product in which the mounting structure is installed.

A mounting structure (10) having a circuit board (11) which can be bent, inside a casing, includes an angle maintaining means which regulates an angle of bending θ of the circuit board (11) as well as maintains a state of contact by bringing in mutual contact mounting components (12 and 13) which are mounted on the circuit board (11) or by bringing the mounting components which are mounted on the circuit board (11) in contact with the circuit board (11), at the time of bending the circuit board (11).

### TECHNICAL FIELD

The present invention relates to a mounting structure in which, a mounting substrate is disposed upon bending in a limited micro space inside a casing.

### BACKGROUND ART

As a mounting structure in which, a mounting substrate is disposed upon bending, a mounting structure described in Patent Literature 1 (Japanese Patent Application Laid-open Publication No. Hei 9-114963) can be cited. As shown in FIG. 12, in the mounting structure described in Patent Literature 1, as a mounting structure of a scanner unit (hereinafter appropriately called as a ‘scanner unit’) 101 of a recording apparatus, a flexible substrate on which components are mounted is disposed upon bending, inside a casing 101a. In this scanner unit 101, small-sizing of the scanner unit 101 is facilitated by deforming the flexible substrate 101 and disposing three-dimensionally an LED light source 114 and other components which are mounted on respective portions of the flexible substrate 110, inside the casing 101a. The LED light source 114 of this scanner unit 101 is installed upon being regulated at a specific angle inside the casing 101a. In this scanner unit 101, positioning of an LED light source mounting portion 113d, or in other words, regulating of an angle of deformation of the flexible substrate is carried out by engaging a claw (not shown in the diagram) provided to the casing 101a with a site near the LED light source mounting portion 113d. In such manner, by an engaging structure and jigs etc., mounting components which are mounted on the flexible substrate 110, or in other words a flexible substrate, had hitherto been disposed three-dimensionally at arbitrary positions.

Patent Literature 1: Japanese Patent Application Laid-open Publication No. Hei 9-114963

### DISCLOSURE OF THE INVENTION

### Problems to be Solved by the Invention

However, in the scanner unit 101 of the Patent Literature 1, for positioning of the LED light source mounting portion 113d, it is necessary to provide a claw portion to the casing 101a. Moreover, it is necessary to provide a place for engaging with the claw portion similarly, on the flexible substrate 110. Consequently, it is necessary to provide newly a structure (a claw portion and an engaging portion) only for disposing the mounting components three-dimensionally inside the casing 101a, which is disadvantageous for small sizing of the mounting structure and of a product in which the mounting structure is installed.

The present invention has been made in view of the abovementioned circumstances, and by deforming a flexible circuit board on which the components are mounted and by bringing in contact the components mounted on the substrate or by fixing upon bringing the components and the substrate in contact at the time of disposing the mounting components at arbitrary positions, it is possible to regulate the positions of mounting of the components, or in other words, an angle of bending of the circuit board, without using any jigs etc. In such manner, an object of the present invention is to provide a mounting structure in which it is possible to dispose the mounting components at arbitrary positions without inhibiting the small-sizing of the mounting structure and of a product in which the mounting structure is installed.

### Means for Solving the Problems

To solve the abovementioned problems and to achieve the object, the mounting structure according to the present invention which is a mounting structure having a circuit board which can be bend, inside a casing includes

an angle maintaining means which regulates an angle of bending of the circuit board and maintains a state of contact by bringing mounting components which are mounted on the circuit board in mutual contact or by bringing the mounting components which are mounted on the circuit board, in contact with the circuit board at the time of bending the circuit board.

In the mounting structure according to the present invention, it is preferable that the angle maintaining means maintains the angle of bending, countering a force of the circuit board tending to bend.

In the mounting structure according to the present invention, the angle maintaining means can fix a place of contact of the mounting components or a place of contact of the mounting components and the circuit board.

In the mounting structure according to the present invention, an angle of bending θ of the circuit board can be expressed by a relationship tan θ=H/L, where, L is a gap between a vertex of an angle of bending of the circuit board, and H is a height of the mounting component.

In the mounting structure according to the present invention, it is preferable that a shape of the mounting components is chamfered or notched such that the place of contact of the mounting components or the place of contact of the mounting component and the circuit board is a surface contact.

In the mounting structure according to the present invention, it is preferable that the circuit board is notched according to a shape of the mounting components such that the place of contact of the mounting components or the place of contact of the mounting component and the circuit board is a surface contact.

### EFFECTS OF THE INVENTION

The mounting structure according to the present invention which is a mounting structure having a circuit board which can be bend, inside a casing, includes an angle maintaining means which regulates an angle of bending of the circuit board and maintains a state of contact by bringing mounting components which are mounted on the circuit board, in mutual contact or by bringing the mounting components which are mounted on the circuit board, in contact with the circuit board at the time of bending the circuit board, thereby making it possible to regulate the angle of bending of the circuit board inside the mounting structure without using a jig, and to dispose the mounting components at arbitrary positions. Consequently, it is possible to provide the mounting structure in which it is possible to dispose the mounting components at arbitrary positions without inhibiting the small-sizing of the mounting structure and of a product in which the mounting structure is installed.

Moreover, in the mounting structure according to the present invention, by the angle maintaining means fixing the place of contact of the mounting components or the place of contact of the mounting component and the circuit board, it is possible to create fixing places for fixing an angle of the circuit board after regulating the angle, without using an area on the circuit board. Consequently, in addition to the abovementioned effect, it is possible to provide a mounting structure in which, a density of mounting on the circuit board is improved, and which is small sized.

Furthermore, in the mounting structure according to the present invention, since it is possible to express an angle of bending θ of the circuit board by a relationship tan θ=H/L, where, L is a gap between a vertex of the angle of bending of the circuit board, and H is a height of the mounting component, it is possible to adjust a shape and a position of the circuit board, and a shape and positions of the mounting components at a designing stage, and to set the angle of bending of the circuit board arbitrarily. Accordingly, it is possible to match a shape of the circuit board according to an object to be installed on the circuit board such as a casing, and to provide a mounting structure which is small-sized to an appropriate shape.

Moreover, in the mounting structure according to the present invention, since a shape of the mounting components is chamfered or notched such that the place of contact of the mounting components or the place of contact of the mounting component and the circuit board is a surface contact, a contact area of the mounting components, and a contact area of the mounting component and the circuit board becomes wide, and the contact becomes stable. Consequently, the contact between the mounting components and the contact between the mounting component and the circuit board becomes stable, and accordingly, it is possible to provide a mounting structure having a circuit board in which, strength and stability as a mounting structure is improved, and in which, reliability is improved.

Furthermore, in the mounting structure according to the present invention, since the circuit board is notched according to a shape of the mounting components such that, the place of contact of the mounting components or the place of contact of the mounting component and the circuit board is a surface contact, a contact area of the mounting components and the circuit board becomes wide, and the contact becomes stable. Accordingly, even in a mounting structure in which, components which cannot be chamfered due to reasons such as there is a functional area near the place of contact, are installed, it is possible to provide a mounting structure in which, the contact between the mounting components and between the mounting component and the circuit board is stabilized, and accordingly, the strength and the stability as a mounting structure is improved, and in which, a reliability is improved.

### BRIEF DESCRIPTION OF THE DRAWINGS

FIG. 1 is a perspective view showing a structure of a mounting structure according to a first embodiment of the present invention;

FIG. 2 is vertical cross-sectional view taken along a line II-II in FIG. 1, showing a structure of a mounting structure according to the first embodiment of the present invention;

FIG. 3 is a vertical cross-sectional view in which, a bent state of a circuit board in the mounting structure according to the first embodiment of the present invention is shown;

FIG. 4 is a vertical cross-sectional view taken along a line II-II in FIG. 1, in which, a positional relationship of a first mounting component and a second mounting component, and a height of the second mounting component are shown;

FIG. 5 is a cross-sectional view corresponding to FIG. 4, showing a state in which, the first mounting component and the second mounting component are brought in contact by bending the circuit board;

FIG. 6 is a vertical cross-sectional view showing a structure of a mounting structure according to a second embodiment of the present invention;

FIG. 7 is a vertical cross-sectional view showing a bent state of a circuit board in the mounting structure according to the second embodiment;

FIG. 8 is a vertical cross-sectional view in which a bent state of a circuit board in a mounting structure according to a modified embodiment of the second embodiment of the present invention is shown;

FIG. 9 is a vertical cross-sectional view showing a structure of a mounting structure according to a third embodiment of the present invention;

FIG. 10 is a vertical cross-sectional view showing a bent state of a circuit board in the mounting structure according to the third embodiment of the present invention;

FIG. 11 is a vertical cross-sectional view showing a bent state of a circuit board in a mounting structure according a fourth embodiment of the present invention; and

FIG. 12 is a cross-sectional view showing a structure of a scanner unit which includes a conventional mounting structure.

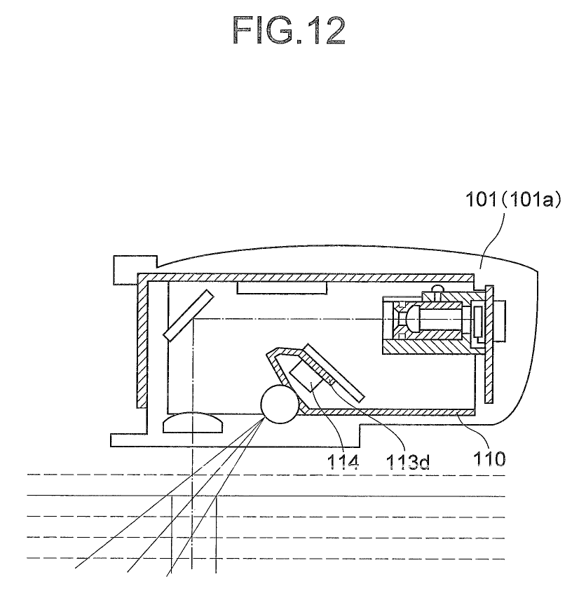

### DESCRIPTION OF REFERENCE NUMERALS

10 mounting structure
11 circuit board
11a vertex of angle of bending
12 first mounting component
13 second mounting component
20 mounting structure
21 circuit board
22 first mounting component
23 second mounting component
23 chamfered area
30 mounting structure
31 circuit board
32 first mounting component
32a notch
33 second mounting component
33a angular portion
40 mounting structure
41 circuit board
45 mounting component
45a angular portion
46 circuit-board hard portion
46a notch
50 mounting structure
51 circuit board
52 first mounting component
53 second mounting component
58 adhesive
59 third mounting component
θ angle of bending

### BEST MODE FOR CARRYING OUT THE INVENTION

Embodiments of a mounting structure according to the present invention will be described below by referring to the accompanying diagrams. However, the present invention is not restricted to the embodiments described below.

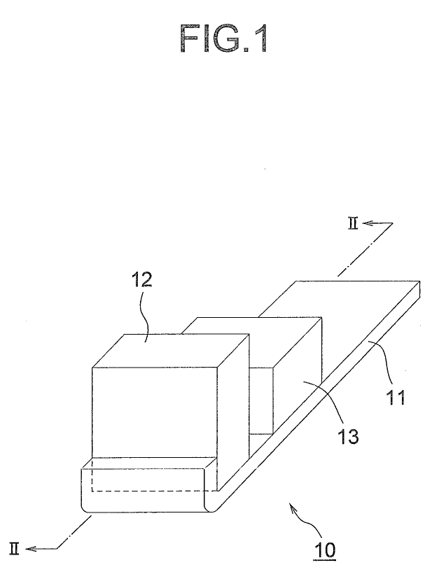

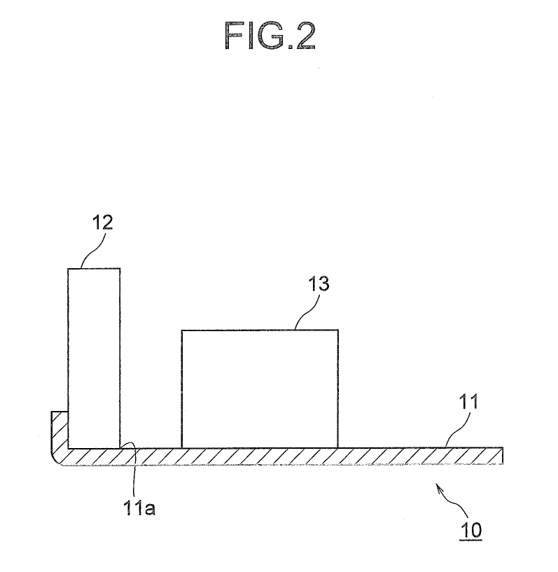

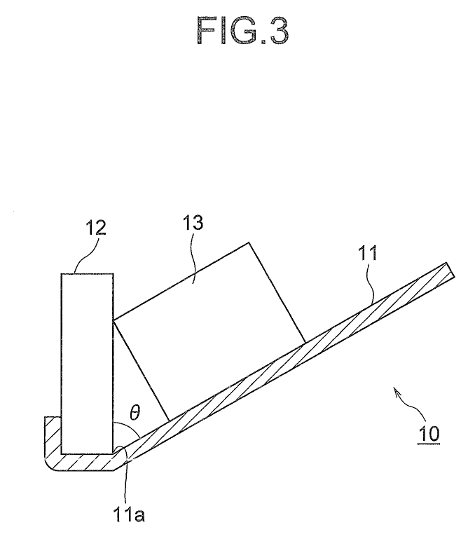

Diagrams from FIG. 1 to FIG. 5 show a mounting structure 10 according to a first embodiment of the present invention. Here, FIG. 1 is a perspective view showing a structure of the mounting structure 10 according to the first embodiment of the present invention. FIG. 2 is a vertical cross-sectional view taken along a line II-II in FIG. 1. FIG. 3 is vertical cross-sectional view corresponding to FIG. 2, showing a state in which a first mounting component 12 and a second mounting component 13 are brought in contact by bending a circuit board 11.

As shown in diagrams from FIG. 1 to FIG. 3, in the mounting structure 10, the first mounting component 12 and the second mounting component 13 are disposed on the circuit board 11 (mounting substrate). The circuit board 11 is a circuit board which is fully or partially flexible, and concretely, is formed by a flexible printed circuit board, or a board having a hybrid structure of a flexible and rigid circuit board in which, a flexible printed circuit board is combined with a hard board (a board such as a printed circuit board, a ceramic board, an Si board, and a metallic board which is not flexible), and apart from this, a circuit board in which, a hard board, or a flexible board, or a board of the hybrid structure is connected to a flexible member such as a cable. The first mounting component 12 and the second mounting component 13, for instance, are active components such as a resistance and a condenser, or passive components such as a semiconductor IC and an image pickup element, or a spacer and a pin, or a connector and a terminal board. These mounting components are fixed on the circuit board 11 by the conductive members such as s solder and a conductive adhesive or the metallic projection electrode.

At the time of bending the circuit board 11 on which the first mounting component 12 and the second mounting component 13 are mounted, from a vertex 11a of an angle of bending, by bringing the first mounting component 12 and the second mounting component 13 in contact as shown in FIG. 3, an arbitrary angle θ is formed. In other words, the first mounting component 12 and the second mounting component 13 function as an angle maintaining means which regulates the angle of bending θ of the circuit board 11 as well as maintains a state of contact made. Moreover, the angle maintaining means in the first embodiment functions to maintain the angle of bending, countering a force of the circuit board 11 tending to bend. The force of the circuit board 11 tending to bend is generated by elasticity of the circuit board 11, but is not restricted to this.

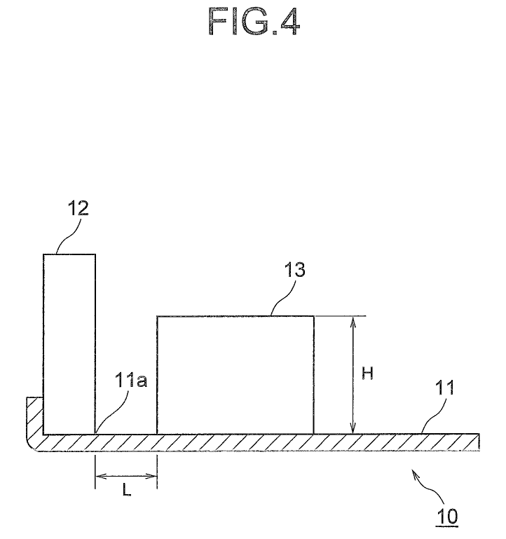

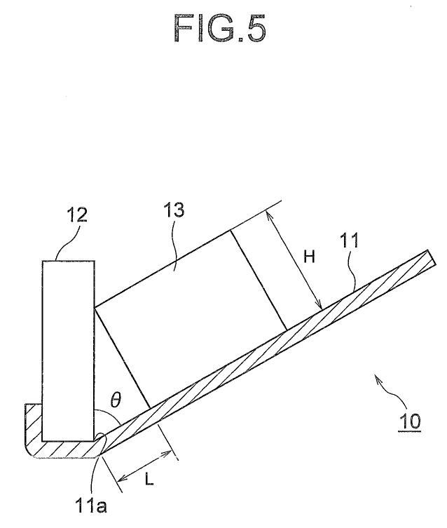

Here, a positional relationship of the first mounting component 12 and the second mounting component 13, and a relationship of the angle of bending θ and a height of the second mounting component 13 will be described by using FIG. 4 and FIG. 5. FIG. 4 is a vertical cross-sectional view along a line II-II in FIG. 1 in which, the positional relationship of the first mounting component 12 and the second mounting component 13, and the height of the second mounting component 13 are shown. FIG. 5 is a vertical cross-sectional view corresponding to FIG. 4, showing a state in which the first mounting component 12 and the second mounting component 13 are brought in contact by bending the circuit board 11.

In FIG. 4 and FIG. 5, the angle of bending 9 is determined by the positional relationship of the first mounting component 12 and the second mounting component 13. In FIG. 4 and FIG. 5, a gap between the vertex (a lower angular portion of the first mounting component) 11a of the angle of bending of the circuit substrate 11 and the second mounting component 13 is let to be L, and the height of the second mounting component 13 is let to be H. In this case, the first mounting component 12 and the second mounting component 13 are disposed such that, when the angle of bending of the circuit substrate 11 which is regulated by bending circuit substrate 11 at the vertex 11a of the angle of bending, and by bringing the first mounting component 12 and the second mounting component 13 in contact is let to be θ, a relationship of θ, H, and L satisfies the following expression (A).

tan θ=H/L: (A)

When the first mounting component 12 and the second mounting component 13 are disposed in such manner, at the step of bending the circuit substrate 11, it is possible to regulate easily the angle of bending θ of the circuit substrate 11 to an arbitrary angle by bringing the first mounting component 12 and the second mounting component 13 in contact, without using any jig.

Next, an effect of the first embodiment will be described.

According to the mounting structure 10 according to the first embodiment, it is possible to dispose the mounting components at arbitrary positions by regulating the angle of bending of the circuit substrate in the mounting structure without using any extra member such as a jig. Consequently, it is possible to provide a mounting structure in which, it is possible to dispose the mounting components at arbitrary positions, without inhibiting small-sizing of the mounting structure and of a product in which the mounting structure is installed.

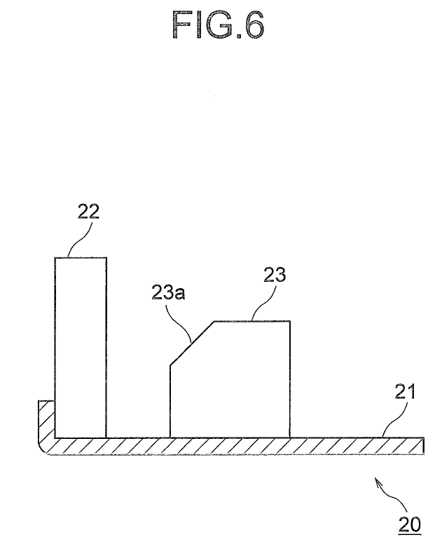

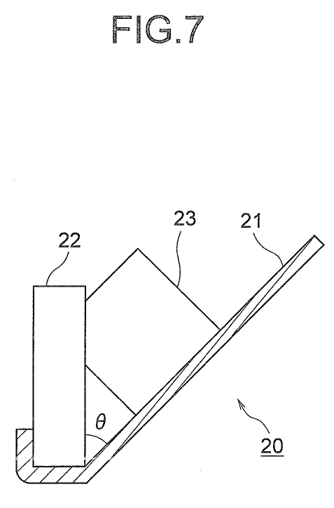

Next, a mounting structure 20 according to a second embodiment of the present invention will be described by using FIG. 6 and FIG. 7. Here, FIG. 6 is a vertical cross-sectional view showing a structure of the mounting structure 20 before bending a circuit substrate 21. FIG. 7 is a vertical cross-sectional view showing a state of the mounting structure 20 after bending.

The mounting structure 20 according to the second embodiment includes the circuit substrate 21, a first mounting component 22, and a second mounting component 23, and as compared with the mounting structure 10 according to the first embodiment, differs at the following points. As shown in FIG. 6 and FIG. 7, in the mounting structure 20 according to the second embodiment, regarding a place of contact of the first mounting component 22 and the second mounting component 23, a chamfered area 23a is formed in the second mounting component 23 by chamfering such that the place of contact of the first mounting component 22 and the second mounting component 23 is a surface contact. In the mounting structure 20, the chamfered area 23a of the first mounting component 22 and the second mounting component 23 functions as an angle maintaining means which regulates the angle of bending θ of the circuit substrate 21, and maintains a state of contact made. As compared to a fact that the place of contact of the first mounting component 12 and the second mounting component 13 of the mounting structure 10 of the first embodiment is a point contact or a line contact, a case in which the contact is let to be a surface contact by providing the chambered area 23a as in the mounting structure 20 according to the second embodiment, the contact of the first mounting component 22 and the second mounting component 23 is stable, and a variation in a shape of a bending structure of the circuit substrate 21 is further suppressed. Wider the chamfered area 23a of the second mounting component 23, more is the contact area of the contact portion and higher is the stability of the bent shape. The angle maintaining means in the second embodiment functions to maintain the angle of bending, countering the force of the circuit board 21 tending to bend, similarly as in the first embodiment. The force of the circuit board 21 tending to bend is generated by elasticity of the circuit board 21, but is not restricted to this.

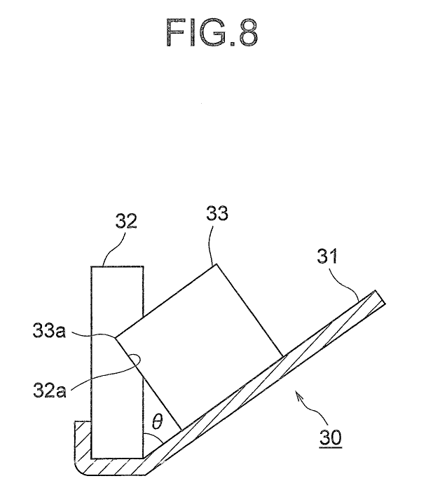

Moreover, in FIG. 8, a mounting structure 30 according to a modified embodiment of the second embodiment is shown. FIG. 8 is a vertical cross-sectional view showing a state of the mounting structure 30 when a circuit board 31 is bent. The mounting structure 30 according to the modified embodiment, includes the circuit board 31, a first mounting component 32, and a second mounting component 33. In this mounting structure 30, a notch 32a having a shape corresponding to an angular portion 33a of the second mounting component 33 is formed in the first mounting component 32, as shown in FIG. 8. In the mounting structure 30, a contact area of the first mounting component 32 and the second mounting component 33 is increased by bringing the angular portion 33a of the second mounting component 33 in contact with the notch 32a of the first mounting component 32 when the circuit board 31 is bent. Consequently, the notch 32a of the first mounting component 32 and the angular portion 33a of the second mounting component 33 function as an angle maintaining means which regulates the angle of bending θ of the circuit substrate 31, and maintains a state of contact made. The angle maintaining means in the modified embodiment functions to maintain the angle of bending, countering the force of the circuit board 31 tending to bend, similarly as in the first embodiment. The force of the circuit board 31 tending to bend is generated by elasticity of the circuit board 31, but is not restricted to this.

As it has been described above, by using the mounting structure 20 (the mounting structure 30) of the second embodiment having the abovementioned structure, it is possible to achieve a circuit board bending structure in which the contact area of the contact portion of the first mounting component 22 (the first mounting component 32) and the second mounting component 23 (the second mounting component 33) is increased and a variation in a shape of the bent structure is suppressed. Accordingly, it is possible to provide a mounting structure in which, manufacturing time is shortened while securing the yield, and cost is reduced.

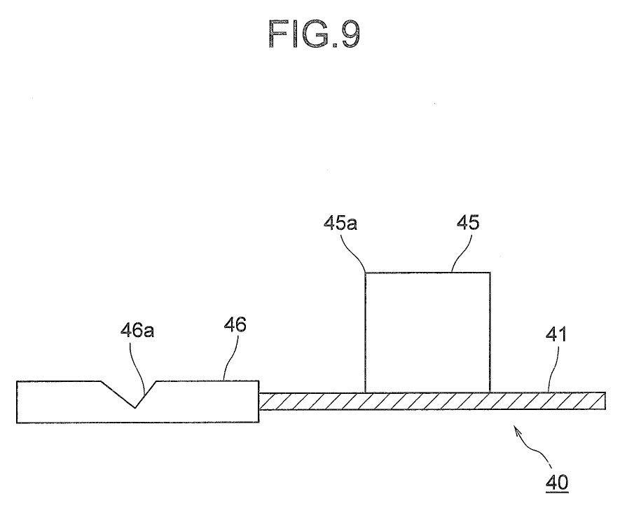

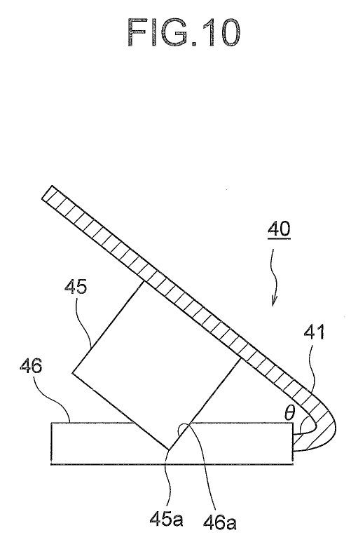

Next, a mounting structure according to a third embodiment of the present invention will be described by using FIG. 9 and FIG. 10. FIG. 9 is a vertical cross-sectional view showing amounting structure of the mounting structure 40 before deformation (bending), and FIG. 10 is a vertical cross-sectional view showing a mounting structure of the mounting structure 40 after deformation.

The mounting structure 40 according to the third embodiment, as compared with the mounting structure according to the first embodiment and the second embodiment, differs at the following points. As shown in FIG. 9 and FIG. 10, in the mounting structure 40 according to the third embodiment of the present invention, when a circuit board 41 is bent, mounting component 45 disposed on the circuit board 41, and a circuit-board hard portion 46 formed at an end portion of the circuit board 41 are brought in contact. A notch 46a having a shape corresponding to an angular portion 45a of the mounting component 45 is provided to the circuit-board hard portion 46. In this mounting structure 40, the angular portion 45a of the mounting component 45 and the notch 46a of the circuit-board hard portion 46 function as an angle maintaining means which regulates the angle of bending θ of the circuit board 41, and which maintains a state of the contact made. A contact area of a place of contact of the mounting component 45 and the circuit-board hard portion 46 is increased by bringing the angular portion 45a of the mounting component 45 in contact with the notch 46a of the circuit-board hard portion 46 when the circuit board 41 is bent. In the mounting structure 40 according to the third embodiment, as the circuit board 41 having the circuit-board hard portion 46, a combined substrate of a hard substrate and a flexible substrate, or, a so-called flexible rigid substrate can be used, but the circuit board is not restricted to such type of substrate. The angle maintaining means in the third embodiment functions to maintain the angle of bending, countering the force of the circuit board 41 tending to bend similarly as in the first embodiment. The force of the circuit board 41 tending to bend is generated by elasticity of the circuit board, but is not restricted to this.

By using the mounting structure 40 according to the third embodiment having the abovementioned structure, the contact area of the mounting component 45 and the circuit-board hard portion 46 becomes wide, and the contact becomes stable. Consequently, even in a mounting structure in which, amounting component which cannot be chamfered due to a presence of a functional area near the place of contact, it is possible to provide a mounting structure in which, the contact of the mounting component and the circuit board is stabilized, and accordingly, a strength and a stability as the mounting structure is improved, and a reliability is improved. Furthermore, it may be a structure in which the substrates are brought in contact.

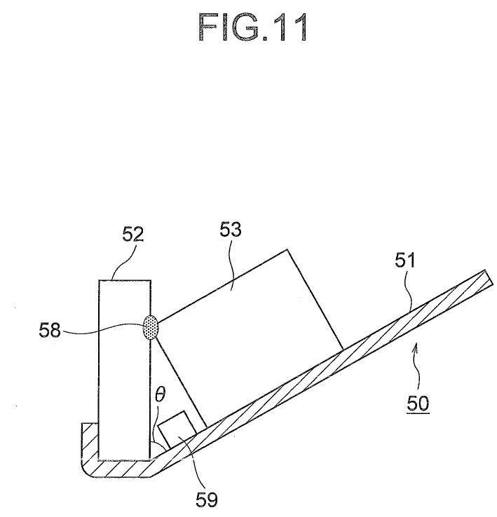

Next, a mounting structure 50 according to a fourth embodiment of the present invention will be described by using FIG. 11. FIG. 11 is a vertical cross-sectional view showing a state of the mounting structure 50 after bending of a circuit board 51.

The mounting structure 50 according to the fourth embodiment of the present invention, as compared with the first embodiment, the second embodiment, and the third embodiment, differs at the following point. As shown in FIG. 11, a place of contact of a first mounting component 52 and a place of contact of a second mounting component 53 are fixed by an adhesive 58. A method of fixing is not restricted to joining by an adhesive, and other means (such as brazing, soldering, and metal joining) may be used. By fixing the place of contact, it is possible to stabilize further the angle of bending of the circuit board 51.

Moreover, by fixing by using the adhesive 58, as a fixing member such as a claw which had been disposed on the circuit board subjected to formation of an angle in the conventional fixing means becomes unnecessary, it is possible to solve a problem in the conventional fixing means where, components cannot be disposed in that area due to the fixing member being disposed on the circuit board. Furthermore, according to the mounting structure 50 according to the fourth embodiment of the present invention, since a third mounting component 59 can be installed while fixing the angle of bending by the adhesive 58, it is possible to create a circuit board structure in which a density of mounting is improved.

By using the mounting structure 50 according to the fourth embodiment having the abovementioned structure, it is possible to create a circuit board in which, the density of mounting is improved while fixing and stabilizing the angle of bending. Consequently, it is possible to provide a mounting structure having improved functions by further stabilizing the angle of bending of the circuit board, and small-sizing, as well as increasing the density of mounting, in addition to an effect by the mounting structures according to the embodiments from the first embodiment to the third embodiment.

### INDUSTRIAL APPLICABILITY

As it has been described above, the mounting structure according to the present invention is useful for small-sizing of a mounting structure which includes a plurality of mounting components on a circuit board, and particularly, is suitable for electronic equipments such as an endoscope, a cellular telephone, and other small-size size electronic equipments.

1. A mounting structure which has a circuit board which can be bent, inside a casing, comprising:
an angle maintaining means which regulates an angle of bending of the circuit board and maintains a state of contact by bringing mounting components which are mounted on the circuit board in mutual contact or by bringing the mounting components which are mounted on the circuit board, in contact with the circuit board at the time of bending the circuit board.

2. The mounting structure according to claim 1, where the angle maintaining means maintains the angle of bending, countering a force of the circuit board tending to bend.

3. The mounting structure according to claim 1, wherein the angle maintaining means fixes a place of contact of the mounting components or a place of contact of the mounting components and the circuit board.

4. The mounting structure according to claim 1, wherein an angle of bending θ of the circuit board is expressed by a relationship tan θ=H/L, where, L is a gap between a vertex of an angle of bending of the circuit board, and H is a height of the mounting component.

5. The mounting structure according to claim 1, wherein a shape of the mounting components is chamfered or notched such that the place of contact of the mounting components or the place of contact of the mounting component and the circuit board is a surface contact.

6. The mounting structure according to claim 1, wherein the circuit board is notched according to a shape of the mounting components such that the place of contact of the mounting components or the place of contact of the mounting component and the circuit board is a surface contact.
